(19) United States
(12) Patent Application Publication
(10) Pub. No.: US 2015/0188029 A1
(43) Pub. Date: Jul. 2, 2015

(54) PIEZOELECTRIC ACTUATOR MODULE, METHOD OF MANUFACTURING THE SAME, AND MEMS SENSOR HAVING THE SAME

(71) Applicant: Samsung Electro-Mechanics Co., Ltd., Gyeonggi-Do (KR)

(72) Inventors: Seung Mo LIM, Gyeonggi-Do (KR); In Young KANG, Gyeonggi-Do (KR); Yun Sung KANG, Gyeonggi-Do (KR); Jeong Suong YANG, Gyeonggi-Do (KR)

(73) Assignee: Samsung Electro-Mechanics Co., Ltd., Gyeonggi-Do (KR)

(21) Appl. No.: 14/293,300

(22) Filed: Jun. 2, 2014

(30) Foreign Application Priority Data
Dec. 26, 2013 (KR) 10-2013-0164221

(51) Int. Cl. H01L 41/113; H01L 41/314; H01L 41/047

(52) U.S. Cl. CPC H01L 41/1132; H01L 41/047; H01L 41/314

(57) ABSTRACT

Embodiments of the invention provide a method of manufacturing a piezoelectric actuator module. The method includes the steps of depositing a second piezoelectric material on one surface of a support layer in a second temperature section, and depositing a first piezoelectric material in a first temperature section to be stacked on the second piezoelectric material. The first temperature section is a higher temperature than the second temperature section and a difference between the first temperature section and the second temperature section ranges from 50° C. to 100° C.

### CROSS REFERENCE TO RELATED APPLICATION

This application claims the benefit of and priority under 35 U.S.C. §119 to Korean Patent Application No. KR 10-2013-0164221, entitled “PIEZOELECTRIC ACTUATOR MODULE, METHOD OF MANUFACTURING THE SAME, AND MEMS SENSOR HAVING THE SAME,” tiled on Dec. 26, 2013, which is hereby incorporated by reference in its entirety into this application.

### BACKGROUND

1. Field of the Invention

The present invention relates to a piezoelectric actuator module, a method of manufacturing the same, and a MEMS sensor having the same.

2. Description of the Related Art

A micro electro mechanical systems (MEMS) is a technology of manufacturing micro mechanical structures, such as a very lame scale integrated circuit, an inertial sensor, a pressure sensor, and an oscillator, by machining silicon, quartz, or glass, as non-limiting examples. The MEMS device has a precision of a micrometer (1/1,000,000 meter) or less, and may structurally be mass produced in a micro product at low cost by being applied with a semiconductor microfabrication technology of repeating a deposition process or an etching process, as non-limiting examples.

Further, in a piezoelectric actuator among the MEMS devices, a piezoelectric material is applied with an electric field and is thus contracted and expanded and a diaphragm coupled with the piezoelectric material may be deformed by the contraction and expansion of the piezoelectric material.

Further, the piezoelectric actuator formed by the above method is implemented as a multi-layered piezoelectric actuator, in which a plurality of piezoelectric materials are stacked, to improve a displacement or a vibration force.

However, the piezoelectric actuator including the plurality of piezoelectric materials, according to the conventional art, for example, U.S. Pat. No. 6,232,701, includes the multi-layered piezoelectric material, but has a problem in that it is very difficult to perform a poling process of the piezoelectric material and thus productivity is degraded.

### SUMMARY

Accordingly, embodiments of the invention have been made in an effort to provide a piezoelectric actuator module, a method of manufacturing the same, and a MEMS sensor having the same, capable of removing a poling process and previously preventing depoling occurring during the following processes since a plurality of piezoelectric materials are deposited in a predetermined temperature section to form a polarization direction and are then imprinted.

According to a first embodiment of the invention, there is provided a method of manufacturing a piezoelectric actuator module. The method includes depositing a second piezoelectric material on one surface of a support layer in a second temperature section, and depositing a first piezoelectric material in a first temperature section to be stacked on the second piezoelectric material. The first temperature section is a higher temperature than the second temperature section and a difference between the first temperature section and the second temperature section ranges from 50° C. to 100° C.

According to an embodiment, the first temperature section ranges from 525° C. to 550° C. and the second temperature section may range from 450° C. to 475° C.

According to an embodiment, the first piezoelectric material and the second piezoelectric material are imprinted to have polarization directions formed in a direction facing each other.

According to an embodiment, a first voltage section, in which the first piezoelectric material is imprinted and output, is lower than a second voltage section, in which the second piezoelectric material imprinted and output.

According to an embodiment, a first age section ranges from −0.86V to −0.28V and a second voltage section ranges from 5.84V to 3.54V.

According to an embodiment, one surface of the first piezoelectric material is formed with an electrode and the electrode is deposited with the second piezoelectric material.

According to a second embodiment of the invention, there is provided a method of manufacturing a piezoelectric actuator module. The method includes depositing a second piezoelectric material on one surface of a support layer in a second temperature section, and depositing a first piezoelectric material in a first temperature section to be stacked on the second piezoelectric material. The first temperature section is a lower temperature than the second temperature section and a difference between the first temperature section and the second temperature section ranges from 50° C. to 100° C.

According to an embodiment, the first temperature section ranges from 450° C. to 475° C. and the second temperature section ranges from 525° C. to 550° C.

According to an embodiment, the first piezoelectric material and the second piezoelectric material are imprinted to have polarization directions formed to be reverberated with respect to a direction coupled with each other.

According to an embodiment, a first voltage section, ire which the first piezoelectric material is imprinted and output, is higher than a second voltage section, in which the second piezoelectric material is imprinted and output.

According to an embodiment, a first voltage section ranges from 5.84V to 3.54 and a second voltage section ranges from −0.86V to −0.28V.

According to an embodiment, one surface of the first piezoelectric material is formed with an electrode and the electrode is deposited with the second piezoelectric material.

According to a third embodiment of the invention, there is provided a piezoelectric actuator module manufactured by the method of manufacturing a piezoelectric actuator module according to the first embodiment of the invention. The piezoelectric actuator module includes a multi-layer including a first piezoelectric material, a second piezoelectric material, and an electrode part, which is connected to the first piezoelectric material and the second piezoelectric material. The piezoelectric actuator module further includes a support layer coupled with the multi-layer, and a support part displaceably supporting the support layer. The first piezoelectric material is deposited in a first temperature section, the second piezoelectric material is deposited in a second temperature section, and the first temperature section is a higher temperature than the second temperature section and a difference between the first temperature section and the second temperature section ranges from 50° C. to 100° C.

According to an embodiment, the first temperature section ranges from 525° C. to 550° C. and the second temperature section ranges from 450° C. to 475° C.

According to an embodiment, the first piezoelectric material and the second piezoelectric material are imprinted to have polarization directions formed in a direction facing each other.

According to an embodiment, a first voltage section, in which the first piezoelectric material is imprinted and output, is lower than a second voltage section, in which the second piezoelectric material is imprinted and output.

According to an embodiment, the first voltage section ranges from −0.86V to −0.28V and the second voltage section ranges from 5.84V to 3.54V.

According to an embodiment, the electrode part of the multi-layer includes a first electrode connected to the first piezoelectric material, a second electrode connected to the second piezoelectric material, and a third electrode disposed between the first piezoelectric material and the second piezoelectric material.

According to an embodiment, for a stacked direction in which the multi-layer is coupled with the support layer, the second electrode is disposed at a lower end of the multi-layer and contacts the support layer, the second piezoelectric material is formed on an upper portion of the second electrode, the third electrode is formed between the second piezoelectric material and the first piezoelectric material, the first piezoelectric material is formed on an upper portion of the third electrode, and the first electrode is formed on an upper portion of the first piezoelectric material.

According to an embodiment, an electrode, to which the first electrode and the second electrode are connected, is a ground electrode.

According to fourth embodiment of the invention, there is provided a piezoelectric actuator module manufactured by the method of manufacturing a piezoelectric actuator module according to the second embodiment of the invention. The piezoelectric actuator module includes a multi-layer including a first piezoelectric material, a second piezoelectric material, and an electrode part, which is connected to the first piezoelectric material and the second piezoelectric material. The piezoelectric actuator module further includes a support layer coupled with the multi-layer, and a support part displaceably supporting the support layer. The first piezoelectric material is deposited in a first temperature section, the second piezoelectric material is deposited in a second temperature section, and the first temperature section is a higher temperature than the second temperature section and a difference between the first temperature section and the second temperature section ranges from 50° C. to 100° C.

According to an embodiment, the first temperature section ranges from 450° C. to 475° C. and the second temperature section ranges from 525° C. to 550° C.

According to an embodiment, the first piezoelectric material and the second piezoelectric material are imprinted to have polarization directions formed to be reverberated with respect to a direction coupled with each other.

According to an embodiment, a first voltage section, in which the first piezoelectric material is imprinted and output, is higher than a second voltage section, in which the second piezoelectric material is imprinted and output.

According to an embodiment, the first voltage section ranges from 5.84V to 3.54V and the second voltage section ranges from −0.86V to −0.28V.

According to an embodiment, the electrode part of the multi-layer includes a first electrode connected to the first piezoelectric material, a second electrode connected to the second piezoelectric material, and a third electrode disposed between the first piezoelectric material and the second piezoelectric material.

According to an embodiment, for a stacked direction, in which the multi-layer is coupled with the support layer, the second electrode is disposed at a lower end of the multi-layer and contacts the support layer, the second piezoelectric material is formed on an upper portion of the second electrode, the third electrode is formed between the second piezoelectric material and the first piezoelectric material, the first piezoelectric material is formed on an upper portion of the third electrode, and the first electrode is formed on an upper portion of the first piezoelectric material.

According to an embodiment, an electrode, to which the first electrode and the second electrode are connected, is a ground electrode.

According to fifth embodiment of the invention, there is provided a MEMS sensor, including a flexible substrate including an excitation unit, a sensor, and a support layer, a mass body connected to the flexible substrate, and a post supporting the flexible substrate. The excitation unit is configured of a multi-layer, which includes a first piezoelectric material, a second piezoelectric material, and an electrode part connected to the first piezoelectric material and the second piezoelectric material. The first piezoelectric material is deposited in a first temperature section, the second piezoelectric material is deposited in a second temperature section, and the first temperature section is a higher temperature than the second temperature section or the first temperature section is a lower temperature than the second temperature section and a difference between the first temperature section and the second temperature section ranges from 50° C. to 100° C.

According to an embodiment, the first temperature section ranges from 525° C. to 550° C. and the second temperature section ranges from 450° C. to 475° C. or the first temperature section ranges from 450° C. to 475° C. and the second temperature section ranges from 525° C. to 550° C.

According to an embodiment, the first piezoelectric material and the second piezoelectric material are imprinted to have polarization directions formed in different directions.

According to an embodiment, when the first temperature section ranges from 525° C. to 550° C. and the second temperature section ranges from 450° C. to 475° C., a first voltage section, in which the first piezoelectric material is imprinted and output, is lower than a second voltage section, in which the second piezoelectric material is imprinted and output.

According to an embodiment, the first voltage section ranges from −0.86V to −0.28V and the second voltage section ranges from 5.84V to 3.54V.

According to an embodiment, when the first temperature section ranges from 450° C. to 475° C. and the second temperature section ranges from 525° C. to 550° C., a first voltage section, in which the first piezoelectric material is imprinted and output, is higher than a second voltage section, in which the second piezoelectric material is imprinted and output.

According to an embodiment, the first voltage section ranges from 5.84V to 3.54V and the second voltage section ranges from −0.86V to −0.28V.

According to an embodiment, the electrode part includes first electrode connected to the first piezoelectric material, a second electrode connected to the second piezoelectric material, and a third electrode disposed between the first piezoelectric material and the second piezoelectric material.

According to an embodiment, for a stacked direction in which the multi-layer is coupled with the support layer, the second electrode is disposed at a lower end of the multi-layer and may contact the support part, the second piezoelectric material is formed on an upper portion of the second electrode, the third electrode is formed between the second piezoelectric material and the first piezoelectric material, and the first piezoelectric material is formed on an upper portion of the third electrode and the first electrode is formed on an upper portion of the first piezoelectric material.

Various objects, advantages and features of the invention will become apparent from the following description of embodiments with reference to the accompanying drawings.

### BRIEF DESCRIPTION OF DRAWINGS

These and other features, aspects, and advantages of the invention are better understood with regard to the following Detailed Description, appended Claims, and accompanying Figures. It is to be noted, however, that the Figures illustrate only various embodiments of the invention and are therefore not to be considered limiting of the invention's scope as it may include other effective embodiments as well.

FIG. 1 is a diagram schematically describing a method of manufacturing a piezoelectric actuator module according to a first embodiment of the invention.

FIGS. 2A to 2D are process flow diagrams schematically illustrating a method of manufacturing a piezoelectric actuator module according to an embodiment of the invention.

FIG. 3 is a configuration diagram schematically illustrating a piezoelectric actuator module manufactured by the method of manufacturing a piezoelectric actuator module illustrated in FIGS. 2A to 2D according to an embodiment of the invention.

FIGS. 4A and 4B are schematic use state diagrams of the piezoelectric actuator module illustrated in FIG. 3 according to the first embodiment of the invention.

FIGS. 5A to 5D are process flow diagrams schematically illustrating a method of manufacturing a piezoelectric actuator module according to a second embodiment of the invention.

FIG. 6 is a configuration diagram schematically illustrating a piezoelectric actuator module manufactured by the method of manufacturing a piezoelectric actuator module illustrated in FIGS. 5A to 5D according to an embodiment of the invention.

FIGS. 7A and 7B are a schematic use state diagram of the piezoelectric actuator module illustrated in FIG. 6 according to an embodiment of the invention.

FIG. 8 is a cross-sectional view schematically illustrating a MEMS sensor including the piezoelectric actuator module according to an embodiment of the invention.

### DETAILED DESCRIPTION

Advantages and features of the present invention and methods of accomplishing the same will be apparent by referring to embodiments described below in detail in connection with the accompanying drawings. However, the present invention is not limited to the embodiments disclosed below and may be implemented in various different forms. The embodiments are provided only for completing the disclosure of the present invention and for fully representing the scope of the present invention to those skilled in the art.

For simplicity and clarity of illustration, the drawing figures illustrate the general manner of construction, and descriptions and details of well-known features and techniques may be omitted to avoid unnecessarily obscuring the discussion of the described embodiments of the invention. Additionally, elements in the drawing figures are not necessarily drawn to scale. For example, the dimensions of some of the elements in the figures may be exaggerated relative to other elements to help improve understanding of embodiments of the present invention. Like reference numerals refer to like elements throughout the specification.

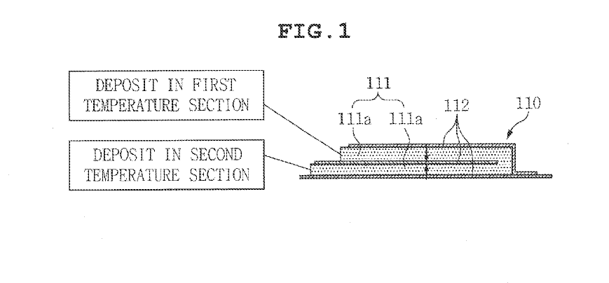

FIG. 1 is a diagram schematically describing a basic concept of a method of manufacturing a piezoelectric actuator module according to an embodiment of the invention.

According to an embodiment of the invention, there is provided a method of manufacturing a piezoelectric actuator module, in which, in a multi-layer in which a multi-layered piezoelectric part is formed, a poling direction is formed by depositing the piezoelectric part in different temperature sections. According to an embodiment, a polarization direction is formed by controlling a deposited temperature condition to imprint the piezoelectric material.

According to an embodiment, as shown in FIG. 1, the multi-layer 110 is contracted or expanded by being applied with a voltage to provide a vibration force and includes a multi-layered piezoelectric part 111 and an electrode part 112.

According to an embodiment, the multi-layered piezoelectric part 111 includes a first piezoelectric material 111a and a second piezoelectric material, in which the first piezoelectric material 111a and the second piezoelectric material are imprinted to have different poling directions.

According to an embodiment, the first piezoelectric material 111a is deposited in a first temperature section and the second deposition section 111b is deposited in a second temperature section.

Further, according to an embodiment the first temperature is a higher temperature than the second temperature or the first temperature section is a lower temperature than the second temperature section and a difference between the first temperature section and the second temperature section ranges from 50° C. to 100° C.

FIG. 1 illustrates an example thereof, in which the piezoelectric materials 111a and 111b are deposited in the first temperature section having a higher temperature than the second temperature section, such that they are imprinted to have the polarization directions formed in a direction facing each other.

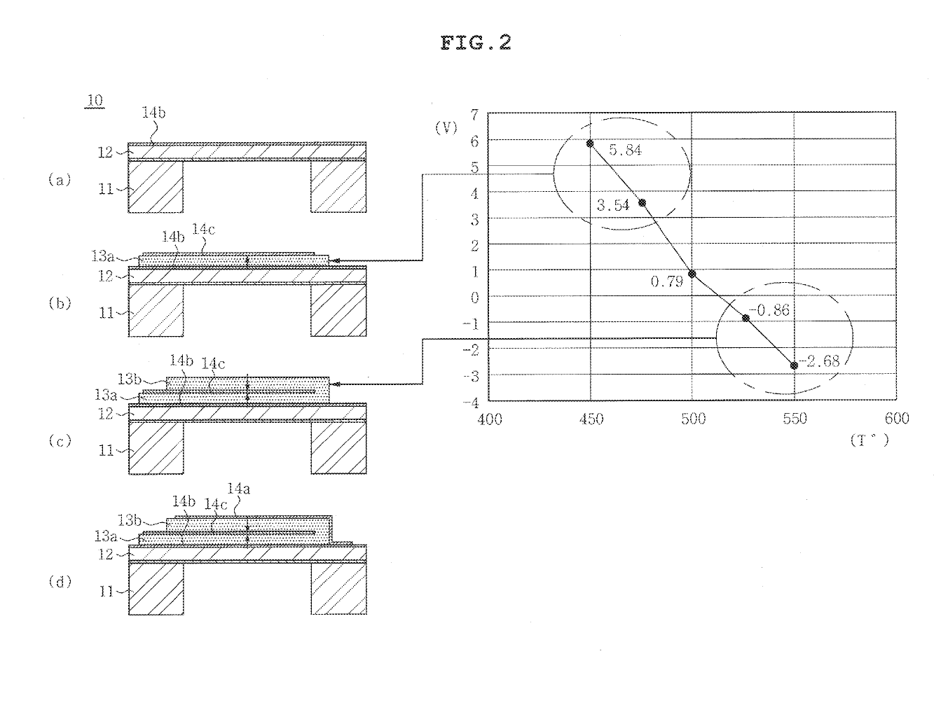

Hereinafter, the detailed preferred embodiment of the method of manufacturing a piezoelectric actuator module will be described in more detail with reference to FIGS. 2A to 2D.

FIGS. 2A to 2D are process flow diagrams schematically illustrating a method of manufacturing a piezoelectric actuator module according to a first embodiment of the invention.

As illustrated in FIGS. 2A to 2D, FIG. 2A illustrates a state in which a support part 11 is coupled with a support layer 12. Further, a lower electrode 14b is formed on one surface of the support layer 12.

Next, FIG. 2B illustrates that a second piezoelectric material 13b is deposited on one surface of the lower electrode 14b, which is formed on the support layer 12, in the second temperature section.

According to an embodiment, the second temperature section ranges from 450° C. to 475° C. Next, an intermediate electrode 14c is formed in the second piezoelectric material 13b.

Next, as illustrated in FIG. 2C, the first piezoelectric material is deposited in the first temperature section to be stacked on the second piezoelectric material 13b.

Further, according to an embodiment, the first temperature section ranges from 525° C. to 550° C. That is, a difference between the first temperature section and the second temperature section ranges from 50° C. to 100° C.

Next, as illustrated in FIG. 2D, an upper electrode 14a is formed to be stacked on the first piezoelectric material 13a and one end of the upper electrode 14a may be connected to the lower electrode 14b.

By the above configuration, as illustrated, the first piezoelectric material 13a and the second piezoelectric material 13b are poled in an opposite direction to each other, and therefore, have the polarization directions formed in a direction facing each other and the multi-layer 110 of the piezoelectric actuator module 10 is supported to the support layer 12 to he expanded or contracted in the same direction as each other.

Further, according to an embodiment, a first voltage section, in which the first piezoelectric material 13a is imprinted and output, is lower than a second voltage section, in which the second piezoelectric material 13b is imprinted and output. Further, the first voltage section ranges from −0.86V to −0.28V and the second voltage section ranges from 5.84V to 3.54V.

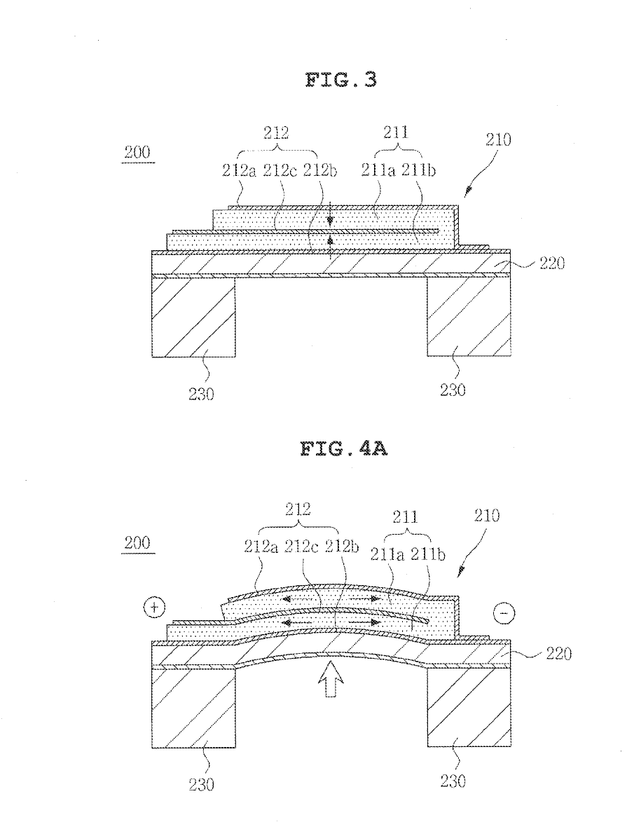

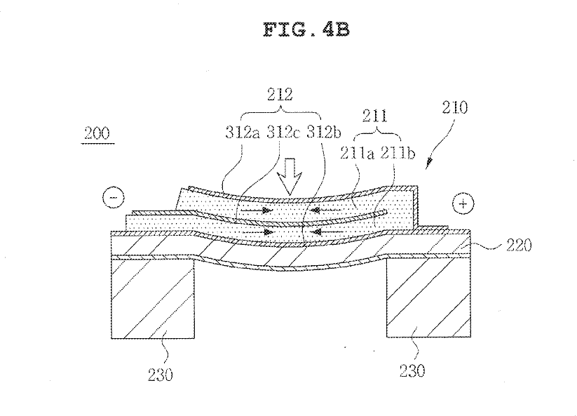

Hereinafter, the piezoelectric actuator module and the use state thereof will be described in more detail with reference to FIGS. 3 and 4.

FIG. 3 is a configuration diagram schematically illustrating a piezoelectric actuator module manufactured by the method of manufacturing a piezoelectric actuator module illustrated in FIGS. 2A to 2D, and FIGS. 4A and 4B are schematic use state diagrams of the piezoelectric actuator module illustrated in FIG. 3, according to various embodiments of the invention.

As illustrated, a piezoelectric actuator module 200 includes a multi-layer 210, a support layer 220, and a support part 230.

According to an embodiment, the multi-layer 210 is contracted or expanded by being applied with an electric field from the outside to provide a vibration force and includes a multi-layered piezoelectric part 211 and an electrode part 212. Further, the support layer 220 displaceably supports the multi-layer 210 in the state in which the multi-layer 210 is coupled with the support layer 220.

According to an embodiment, the multi-layer 210 is coupled with the support layer 220 and the support layer 220 is displaceably supported to the support part 230.

According to an embodiment, the multi-layered piezoelectric part 211 includes a first piezoelectric material 211a and a second piezoelectric material and as illustrated in FIGS. 2A to 2D, as the first piezoelectric material 211a and the second piezoelectric material 211b are each deposited in the first temperature section and the second temperature section, as illustrated by an arrow, they are imprinted to form different poling directions, that is, have the polarization directions formed in a direction facing each other.

Further, according to an embodiment, the first temperature section is a higher temperature than the second temperature section.

According to an embodiment, the first temperature section ranges from 525° C. to 550° C. and the second temperature section ranges from 450° C. to 475° C., such that the difference between the first temperature section and the second temperature section ranges from 50° C. to 100° C.

Further, a first voltage section, in which the first piezoelectric material 211a is imprinted and output, is lower than a second voltage section, in which the second piezoelectric material 211b is imprinted and output. Further, the first voltage section ranges from −0.86V to −0.28V and the second voltage section ranges from 5.84V to 3.54V.

Further, according to an embodiment, the electrode part 212 includes a first electrode 212a, a second electrode 212b, and a third electrode 212c, which are each connected to the multi-layered piezoelectric part 211.

According to an embodiment, the first electrode 212a is connected to the first piezoelectric material 211a, the second electrode 212b is connected to the second piezoelectric material 211b, and the third electrode 212c is disposed between the first piezoelectric material 211a and the second piezoelectric material 211b.

Further, according to an embodiment, the electrode, to which the first electrode 212a and the second electrode 212b are connected, is used as a ground electrode.

Therefore, for the stacked direction, in which the multi-layer 210 is coupled with the support layer 220, the second electrode 212b is formed at a lower portion of the multi-layer 210 and is partially coupled with the support layer 220, the second piezoelectric material 211b is formed on the second electrode 212b, the third electrode 212c is formed between the second piezoelectric material 211b and the first piezoelectric material 211a, the first piezoelectric material 211a is formed on the third electrode 212c, and the first electrode 212a is formed on the first piezoelectric material 211a.

By the above configuration, in the multi-layer 210, the first electrode 212a is formed of an upper electrode, the second electrode 212b is formed of a lower electrode, and the third electrode 212c is formed of an intermediate electrode, the first electrode 212a is disposed on a top layer of the multi-layer 210, and the second electrode 212b is disposed on a bottom layer of the multi-layer 210.

Further, according to an embodiment, the support part 230 is coupled with an end of the support layer 210 to displaceably support the support layer 210. Therefore, some region, in which the support layer 220 does not contact the support part 230, is exposed to the outside.

FIGS. 4A and 4B are schematic use state diagrams of the piezoelectric actuator module illustrated in FIG. 3 according to an embodiment of the invention. As illustrated in FIG. 4A, when an electric field is applied to an electrode to which the first electrode 212a and the second electrode 212b of the multi-layer 210 of the piezoelectric actuator module 200 are connected and the third electrode 212c, respectively, for example, when as illustrated by + and −, a − voltage is applied to the electrode to which the first electrode 212a and the second electrode 212b are connected and a + voltage is applied to the third electrode, as illustrated by an arrow, the first piezoelectric material 211a and the second piezoelectric material 211b are simultaneously expanded. Further, a central portion of the multi-layer 210 is displaced upward as illustrated by an arrow in the state in which the multi-layer 210 is supported to the support layer 220.

Unlike this, as illustrated in FIG. 4B, when an electric field opposite to that of FIG. 4A is applied to an electrode to which the first electrode 212a and the second electrode 212b of the multi-layer 210 of the piezoelectric actuator module 200 are connected and the third electrode 212c, respectively, that is, when the + voltage is applied to the electrode to which the first electrode 212a and the second electrode 212b are connected and the − voltage is applied to the third electrode, as illustrated by an arrow, the first piezoelectric material 211a and the second piezoelectric material 211b are simultaneously contracted.

Therefore, a central portion of the multi-layer 210 is displaced downward as illustrated by an arrow in the state in which the multi-layer 210 is supported to the support layer 220.

By the above configuration, the piezoelectric actuator module 200 manufactured by the method of manufacturing a piezoelectric actuator module according to the first embodiment of the invention has high driving characteristics as the first piezoelectric material 211a and the second piezoelectric material 211b are imprinted by the deposition process of the piezoelectric material without performing the poling process and thus is contracted and expanded in the same direction, high productivity as the separate poling process is not required, and high reliability as the deterioration due to heat is prevented.

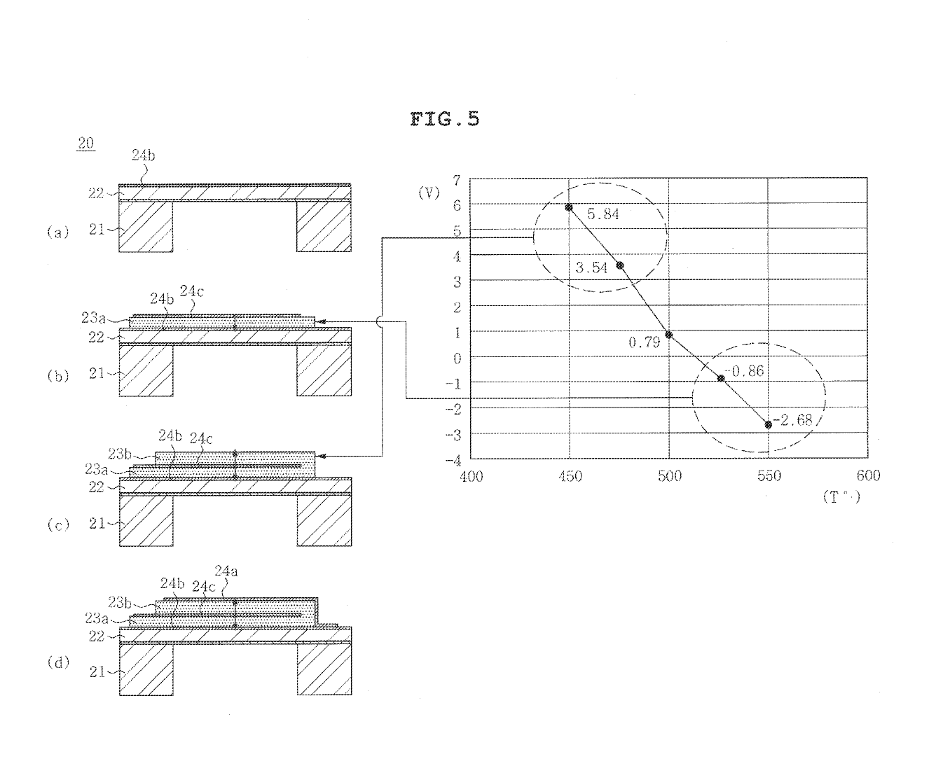

FIGS. 5A to 5D are process flow diagrams schematically illustrating a method of manufacturing a piezoelectric actuator module according to a second embodiment of the present invention. Further, a method of manufacturing a piezoelectric actuator module according to the second embodiment of the present invention is different from the method of manufacturing a piezoelectric actuator module according to the first embodiment of the invention in view of only the temperature section and the voltage section, in which each piezoelectric material is deposited.

According to an embodiment, FIG. 5A illustrates a state, in which a support part 21 is coupled with a support layer 22. Further, a lower electrode 24b is formed on one surface of the support layer 22 and FIG. 5B illustrates that a second piezoelectric material 23b is deposited on one surface of the lower electrode 24b, which is formed on one surface of the support layer 22, in the second temperature section. Further, the second temperature section may range from 525° C. to 550° C. Further, an intermediate electrode 24b is formed in the second piezoelectric material 23b.

Next, as illustrated in FIG. 5C, the first piezoelectric material 23a is deposited in the first temperature section to be stacked on the first piezoelectric material 13b.

Further, according to an embodiment, the first temperature section ranges from 450° C. to 475° C. Thus, a difference between the first temperature section and the second temperature section ranges from 50° C. to 100° C.

Next, as illustrated in FIG. 5D, an upper electrode 24a is formed to be stacked on the first piezoelectric material 13a and one end of the upper electrode 24a is connected to the lower electrode 24b.

By the above configuration, as illustrated, the first piezoelectric material 23a and the second piezoelectric material 23b are poled in an opposite direction to each other, that is, have polarization directions each formed to reverberate a direction in which the first piezoelectric material is coupled with the second piezoelectric material and the multi-layer 21 of the piezoelectric actuator module 20 is supported to the support layer 22 to be expanded or contracted in the same direction as each other.

According to an embodiment, the first voltage section, in which the first piezoelectric material is imprinted and output, is higher than the second voltage section, in which the second piezoelectric material is imprinted and output. In more detail, the first voltage section ranges from 5.84V to 3.54V and the second voltage section ranges from −0.86V to −0.28V.

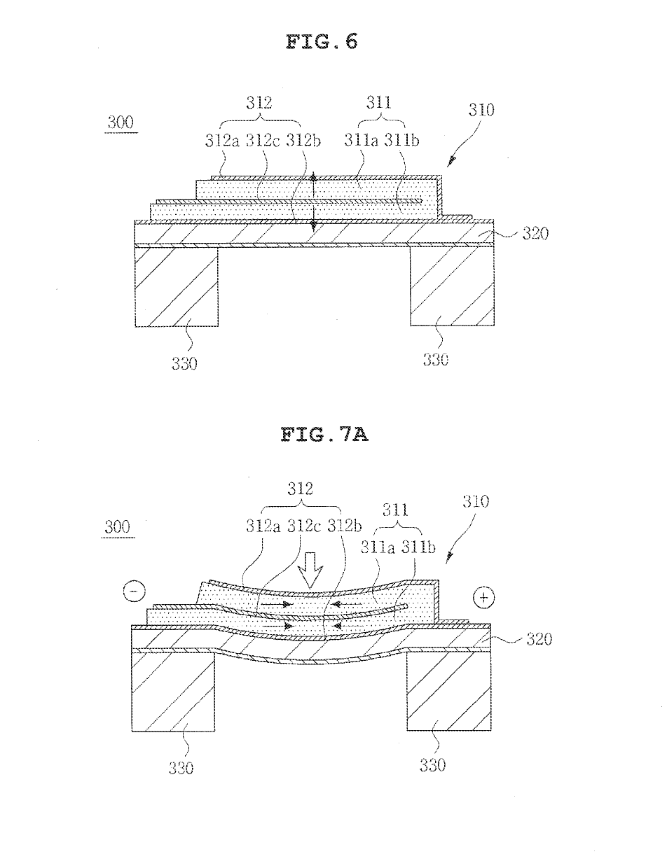

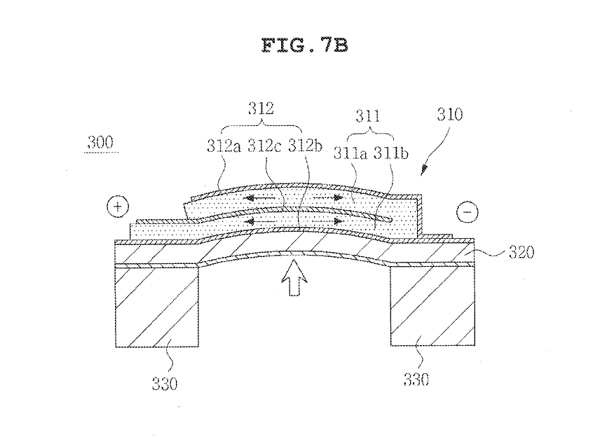

Hereinafter, the piezoelectric actuator module manufactured by the method of manufacturing a piezoelectric actuator module according to the second embodiment of the invention and the use state thereof will be described in more detail with reference to FIGS. 6 and 7.

FIG. 6 is a configuration diagram schematically illustrating a piezoelectric actuator module manufactured by the method of manufacturing a piezoelectric actuator module illustrated in FIGS. 5A to 5D and FIGS. 7A and 7B are schematic use state diagrams of the piezoelectric actuator module illustrated in FIG. 6 according to various embodiments of the invention. Further, a piezoelectric actuator module 300 is different from the piezoelectric actuator module 200 illustrated in FIG. 3 in view of only the polarized direction. Thus, as the polarization direction is illustrated by an arrow, the piezoelectric actuator module 200 manufactured by the manufacturing method according to the first embodiment of the invention is formed to be towards surfaces facing each other, while as the polarization direction is illustrated by an arrow, the piezoelectric actuator module 300 manufactured by the manufacturing method according to the second embodiment of the invention is formed to be reverberated with respect to directions coupled with each other.

According to an embodiment, the piezoelectric actuator module 300 includes a multi-layer 310, a support layer 320, and a support part 330.

Further, according to an embodiment, the multi-layer 310 includes a multi-layer piezoelectric part 311 and electrode part 312. Further, the support part 330 displaceably supports the multi-layer 310 in the state in which the multi-layer 310 is coupled with the support layer 320.

Thus, the multi-layer 310 is coupled with the support layer 320 and the support layer 320 is displaceably supported to the support part 330.

Further, according to an embodiment, the multi-layered piezoelectric part 311 includes a first piezoelectric material 311a and a second piezoelectric material 311b and as illustrated in FIGS. 2A to 2D, as the first piezoelectric material 311a and the second piezoelectric material 311b are each deposited in the first temperature section and the second temperature section, as illustrated by an arrow, they are imprinted to form different poling directions, that is, have the polarization directions each formed to be reverberated with respect to directions coupled with each other.

Further, according to an embodiment, the first temperature section is a lower temperature than the second temperature section and the difference between the first temperature section and the second temperature section ranges from 50° C. to 100° C., in more detail, the first temperature section ranges from 450° C. to 475° C. and the second temperature section ranges from 525° C. to 550° C.

Further, according to an embodiment, a first voltage section, in which the first piezoelectric material 311a is imprinted and output, is higher than a second voltage section, in which the second piezoelectric material 311b is imprinted and output. Further, the first voltage section ranges from 5.84V to 3.54V and the second voltage section ranges from −0.86V to −0.28V.

Further, according to an embodiment, the electrode part 312 includes a first electrode 312a, a second electrode 312b, and a third electrode 312c, which are each connected to the multilayered piezoelectric part 311.

Further, according to an embodiment, an organic coupling and a detailed shape of the first piezoelectric material 311a and the second piezoelectric material 311b and the first electrode 312a, the second electrode 312b, and the third electrode 312c are the same as the technical configuration of the piezoelectric actuator module 200 illustrated in FIG. 3.

FIGS. 7A and 7B are schematic use state diagrams of the piezoelectric actuator module illustrated in FIG. 6 according to an embodiment of the invention. As illustrated in FIG. 7A, when an electric field is applied to an electrode to which the first electrode 312a and the second electrode 312b of the multi-layer 310 of the piezoelectric actuator module 300 are connected and the third electrode 312c, respectively, for example, when as illustrated by + and −, a + voltage is applied to the electrode to which the first electrode 312a and the second electrode 312b are connected and a − voltage is applied to the third electrode, as illustrated by an arrow, the first piezoelectric material 311a and the second piezoelectric material 311b are simultaneously contracted. Further, a central portion of the multi-layer 310 is displaced downward as illustrated by an arrow in the state in which the multi-layer is supported to the support layer 320.

Unlike this, as illustrated in FIG. 7B, when an electric field opposite to that of FIG. 7A is applied to an electrode to which the first electrode 311a and the second electrode 312b of the multi-layer 310 of the piezoelectric actuator module 300 are connected and the third electrode 312c, respectively, that is, when the − voltage is applied to the electrode to which the first electrode 312a and the second electrode 312b are connected and the + voltage is applied to the third electrode, as illustrated by an arrow, the first piezoelectric material 311a and the second piezoelectric material 311b are simultaneously expanded.

Therefore, a central portion of the multi-layer 310 is displaced upward as illustrated by an arrow in the state in which the multi-layer is supported to the support layer 320.

By the above configuration, the piezoelectric actuator module 300 manufactured by the method of manufacturing a piezoelectric actuator module according to the second embodiment of the invention has high driving characteristics as the first piezoelectric material 311a and the second piezoelectric material 311b are imprinted by the deposition process of the piezoelectric material without performing the poling process and thus is contracted and expanded in the same direction, high productivity as the separate poling process is not required, and high reliability as the deterioration due to heat is prevented.

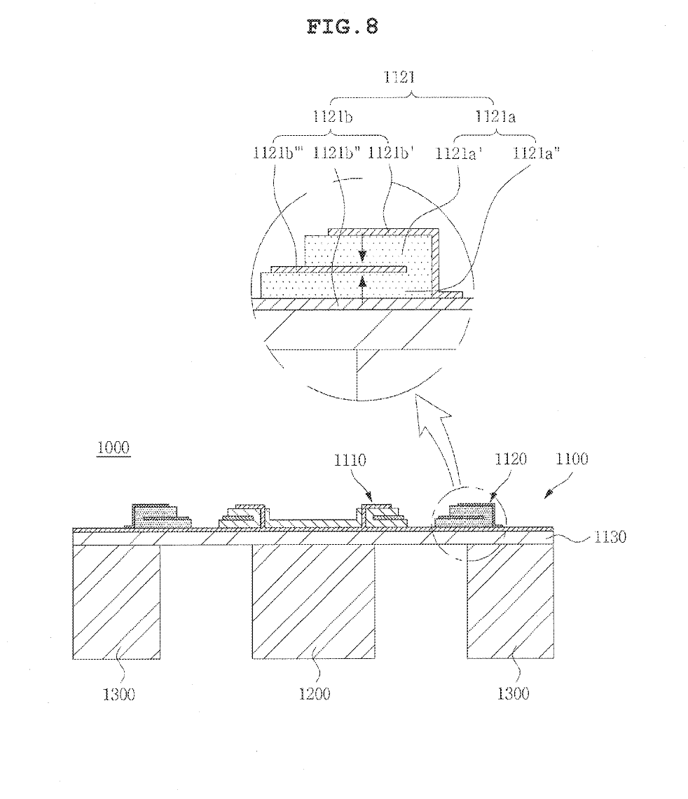

FIG. 8 is a cross-sectional view schematically illustrating a MEMS sensor including the piezoelectric actuator module according to an embodiment of the invention. As illustrated, an angular velocity sensor 1000 includes a flexible substrate part 1100, a mass body 1200, and a post 1130.

According to an embodiment, the mass body 1200 is displaced by an inertial force, a Coriolis force, an external force, a driving force, and the like and is coupled with the flexible substrate part 1100.

Further, according to an embodiment, the flexible substrate part 1100 includes a sensor 1110, an excitation unit 1120, and a support layer 1130, in which the support layer 1130 is formed with the sensor 1110 and the excitation unit 1120. Further, as the flexible substrate part 1100 is coupled with the post 1300, the mass body 1200 is displaceably supported to the post 1300 in a flowing state by the flexible substrate part 1100 in a floating state.

Further, according to an embodiment, the excitation unit 1120 of the flexible substrate part 1100 may be configured as the piezoelectric actuator module illustrated in FIG. 1. To this end, the excitation unit 1120 includes a multi-layer 1121.

In addition, according to an embodiment, the sensor 1110 is formed in a piezoelectric type, a piezoresistive type, a capacitive type, an optical scheme, as non-limiting examples, but is not particularly limited thereto.

According to an embodiment, the multi-layer 1121 is contracted or expanded by being applied with an electric field from the outside to provide a vibration force and similar to the multi-layer illustrated in FIG. 3, includes a multi-layered piezoelectric part 1121a and an electrode part 1121b and as illustrated by an arrow, the polarization direction is formed to be towards surfaces facing each other.

Further, according to an embodiment, in the multi-layer 1121, the multi-layered piezoelectric material is simultaneously expanded or contracted in the same direction.

According to an embodiment, the multilayered piezoelectric part 1121a includes a first piezoelectric material 1121a′ and a second piezoelectric material 1121a″, in which the first piezoelectric material 1121a′ is stacked on the second piezoelectric material 1121a″.

Next, the electrode part 1121b includes a first electrode 1121b′, a second electrode 1121b″, and a third electrode 1121b′″.

According to an embodiment, the first electrode 1121b′ is connected to the first piezoelectric material 1121a′, the second electrode 1121b′ is connected to the second piezoelectric material 1121a″, and the third electrode 1121b′″ is disposed between the first piezoelectric material 1121a′ and the second piezoelectric material 1121a″, Further, the first piezoelectric material 1121a′ and the second piezoelectric material 1121a″ are each deposited in the first temperature section and the second temperature section as illustrated in FIGS. 2A to 2D.

Further, the first temperature section is a higher temperature than the second temperature section or the first temperature section is a lower temperature than the second temperature section and the difference between the first temperature section and the second temperature section ranges from 50° C. to 100° C.

According to an embodiment, the first temperature section ranges from 525° C. to 550° C. and the second temperature section ranges from 450° C. to 475° C.

According to an embodiment, the first temperature section ranges from 450° C. to 475° C. and the second temperature section ranges from 525° C. to 550° C.

Further, According to an embodiment, FIG. 8 illustrates an embodiment thereof and the first temperature section is a higher temperature than the second temperature section and the first piezoelectric material and the second piezoelectric material have the polarization directions formed in a direction facing each other.

Further, According to an embodiment, when the first temperature section ranges from 525° to 550° and the second temperature section ranges from 450° C. to 475° C., the first voltage section, in which the first piezoelectric material is imprinted and output, is lower than the second voltage section, in which the second piezoelectric material is imprinted and output, and the first voltage section ranges from −0.86V to −0.28V and the second voltage section ranges from 5.84V to 3.54V.

Further, according to an embodiment, when the first temperature section ranges from 450° C. to 475° C. and the second temperature section ranges from 525° C. to 550° C., the first voltage section, in which the first piezoelectric material is imprinted and output, is higher than the second voltage section, in which the second piezoelectric material is imprinted and output, and the first voltage section ranges from 5.84V to 3.54V and the second voltage section ranges from −0.86V to −0.28V.

According to an embodiment, for the stack direction in which the multi-layer 1121 is coupled with the support layer 1130, the second electrode 1121b″ is formed at a lower end of the multi-layer 1121 and contacts the support layer 1130, the second piezoelectric material 1121a″ is formed on an upper portion of the second electrode 1121b″ the third electrode. 1.121b′″ is formed between the second piezoelectric material 1121a″ and the first piezoelectric material 1121a′, the first piezoelectric material 1121a′ is formed on an upper portion of the third electrode 1121b′″ and the first electrode 1121b′ is formed on an upper portion of the first piezoelectric material 1121a′.

By the above configuration, in the multi-layer 1121, the first electrode 1121b′ is formed as an upper electrode, the second electrode 1121b″ is formed as a lower electrode, and the third electrode 1121b′″ is formed as an intermediate electrode and the first electrode 1121b′ is disposed on an uppermost layer of the multi-layer 1121 and the second electrode 1121b″ is disposed on a lowermost layer of the multi-layer 1121.

According to an embodiment, when a voltage is applied to the first electrode 1121b′ and the second electrode 1121b″ respectively, so as to sense an angular velocity, since the excitation unit 1120 is vibrated and the excitation unit is vibrate at high efficiency by the multi-layered piezoelectric part 1121a, the angular velocity sensor including the piezoelectric actuator module configured as described above and according to various embodiments of the invention is implemented as the MEMS sensor, which may implement the more accurate sensing.

Further, the MEMS sensor according to another embodiment of the invention, is implemented by the MEMS sensor, which includes the piezoelectric actuator module manufactured by the method of manufacturing a piezoelectric actuator module according to the second embodiment of the present invention illustrated in FIG. 6.

According to the various embodiments of the invention, it is possible to provide the piezoelectric actuator module, the method of manufacturing the same, and the MEMS sensor having the same capable of removing the poling process and previously preventing the depoling occurring during the following processes since the plurality of piezoelectric materials are deposited in the predetermined temperature section to form a polarization direction and are then imprinted.

Terms used herein are provided to explain embodiments, not limiting the present invention. Throughout this specification, the singular form includes the plural form unless the context clearly indicates otherwise. When terms “comprises” and/or “comprising” used herein do not preclude existence and addition of another component, step, operation and/or device, in addition to the above-mentioned component, step, operation and/or device.

Embodiments of the present invention may suitably comprise, consist or consist essentially of the elements disclosed and may be practiced in the absence of an element not disclosed. For example, it can be recognized by those skilled in the art that certain steps can be combined into a single step.

The terms and words used in the present specification and claims should not be interpreted as being limited to typical meanings or dictionary definitions, but should be interpreted as having meanings and concepts relevant to the technical scope of the present invention based on the rule according to which an inventor can appropriately define the concept of the term to describe the best method he or she knows for carrying out the invention.

The terms “first,” “second,” “third,” “fourth,” and the like in the description and in the claims, if any, are used for distinguishing between similar elements and not necessarily for describing a particular sequential or chronological order. It is to be understood that the terms so used are interchangeable under appropriate circumstances such that the embodiments of the invention described herein are, for example, capable of operation in sequences other than those illustrated or otherwise described herein. Similarly, if a method is described herein as comprising a series of steps, the order of such steps as presented herein is not necessarily the only order in which such steps may be performed, and certain of the stated steps may possibly be omitted and/or certain other steps not described herein may possibly be added to the method.

The singular forms “a,” “an,” and “the” include plural referents, unless the context clearly dictates otherwise.

As used herein and in the appended claims, the words “comprise,” “has,” and “include” and all grammatical variations thereof are each intended to have an open, non-limiting meaning that does not exclude additional elements or steps.

As used herein, the terms “left,” “right,” “front,” “back,” “top,” “bottom,” “over,” “under,” and the like in the description and in the claims, if any, are used for descriptive purposes and not necessarily for describing permanent relative positions. It is to be understood that the terms so used are interchangeable under appropriate circumstances such that the embodiments of the invention described herein are, for example, capable of operation in other orientations than those illustrated or otherwise described herein. The term “coupled,” as used herein, is defined as directly or indirectly connected in an electrical or nonelectrical manner. Objects described herein as being “adjacent to” each other may be in physical contact with each other, in close proximity to each other, or in the same general region or area as each other, as appropriate for the context in which the phrase is used. Occurrences of the phrase “according to an embodiment” herein do not necessarily all refer to the same embodiment.

Ranges may be expressed herein as from about one particular value, and/or to about another particular value. When such a range is expressed, it is to be understood that another embodiment is from the one particular value and/or to the other particular value, along with all combinations within said range.

Although the present invention has been described in detail, it should be understood that various changes, substitutions, and alterations can be made hereupon without departing from the principle and scope of the invention. Accordingly, the scope of the present invention should be determined by the following claims and their appropriate legal equivalents.

What is claimed is:

1. A method of manufacturing a piezoelectric actuator module, comprising:
depositing a second piezoelectric material on one surface of a support layer in a second temperature section; and
depositing a first piezoelectric material in a first temperature section to be stacked on the second piezoelectric material,
wherein the first temperature section is a higher temperature than the second temperature section and a difference between the first temperature section and the second temperature section ranges from 50° C. to 100° C.

2. The method according to claim 1, wherein the first temperature section ranges from 525° C. to 550° C. and the second temperature section ranges from 450° C. to 475° C.

3. The method according to claim 1, wherein the first piezoelectric material and the second piezoelectric material are imprinted to have polarization directions formed in a direction facing each other.

4. The method according to claim 3, wherein a first voltage section, in which the first piezoelectric material is imprinted and output,is lower than a second voltage section, in which the second piezoelectric material is imprinted and output.

5. The method according to claim 1, wherein a first voltage section ranges from −0.86V to −0.28V and a second voltage section ranges from 5.84V to 3.54V.

6. The method according to claim 1, wherein one surface of the first piezoelectric material is formed with an electrode and the electrode is deposited with the second piezoelectric material.

7. A method of manufacturing a piezoelectric actuator module, comprising;
depositing a second piezoelectric material on one surface of a support layer in a second temperature section; and
depositing a first piezoelectric material in a first section so as to be stacked on the second piezoelectric material,
wherein the first temperature section is a lower temperature than the second temperature section and a difference between the first temperature section and the second temperature section ranges from 50° C. to 100° C.

8. The method according to claim 7, wherein the first temperature section ranges from 450° C. to 475° C. and the second temperature section ranges from 525° C. to 550° C.

9. The method according to claim 7, wherein the first piezoelectric material and the second piezoelectric material are imprinted to have polarization directions formed to be reverberated with respect to a direction coupled with each other.

10. The method according to claim 9, wherein a first voltage section, in which the first piezoelectric material is imprinted and output, is higher than a second voltage section, in which the second piezoelectric material is imprinted and output.

11. The method according to claim 9, wherein a first voltage section ranges from 5.84V to 3.54V and a second voltage section ranges from −0.86V to −0.28V.

12. The method according to claim 7, wherein one surface of the first piezoelectric material is limited with an electrode and the electrode is deposited with the second piezoelectric material.

13. A piezoelectric actuator module manufactured by the method of manufacturing a piezoelectric actuator module according to in claim 1, the piezoelectric actuator module comprising:
a multi-layer including a first piezoelectric material, a second piezoelectric material, and an electrode part, which is connected to the first piezoelectric material and the second piezoelectric material;
a support layer coupled with the multi-layer; and
a support part displaceably supporting the support layer,
wherein the first piezoelectric material is deposited in a first temperature section,
wherein the second piezoelectric material is deposited in a second temperature section, and
wherein the first temperature section is a higher temperature than the second temperature section and a difference between the first temperature section and the second temperature section ranges from 50° C. to 100° C.

14. The piezoelectric actuator module according to claim 13, wherein the first temperature section ranges from 525° C. to 550° C. and the second temperature section ranges from 450° C. to 475° C.

15. The piezoelectric actuator module according to claim 13, wherein the first piezoelectric material and the second piezoelectric material are imprinted to have polarization directions formed in a direction facing each other.

16. The piezoelectric actuator module according to claim 15, wherein a first voltage section, in which the first piezoelectric material is imprinted and output, is lower than a second voltage section, in which the second piezoelectric material is imprinted and output.

17. The piezoelectric actuator module according to claim 16, wherein the first voltage section ranges from −0.86V to −0.28V and the second voltage section ranges from 5.84V to 3.54V.

18. The piezoelectric actuator module according to claim 13, wherein the electrode part of the multi-layer comprises:
a first electrode connected to the first piezoelectric material;
a second electrode connected to the second piezoelectric material; and
a third electrode disposed between the first piezoelectric material and the second piezoelectric material.

19. The piezoelectric actuator module according to claim 18, wherein for a stacked direction in which the multi-layer is coupled with the support layer,
wherein the second electrode is disposed at a lower end of the multi-layer and contacts the support layer,
wherein the second piezoelectric material is formed on an upper portion of the second electrode,
wherein the third electrode is formed between the second piezoelectric material and the first piezoelectric material,
wherein the first piezoelectric material is formed on an upper portion of the third electrode, and
wherein the first electrode is formed on an upper portion of the first piezoelectric material.

20. The piezoelectric actuator module according to claim 19, wherein an electrode to which the first electrode and the second electrode are connected is a ground electrode.

21. A piezoelectric actuator module manufactured by the method of manufacturing a piezoelectric actuator module according, to claim 7, the piezoelectric actuator module comprising:
a multi-layer including a first piezoelectric material, a second piezoelectric material, and an electrode part, which is connected to the first piezoelectric material and the second piezoelectric material;
a support layer coupled with the multi-layer; and
a support part displaceably supporting the support layer,
wherein the first piezoelectric material is deposited is a first temperature section,
wherein the second piezoelectric material is deposited in a second temperature section, and
wherein the first temperature section is a higher temperature than the second temperature section and a difference between the first temperature section and the second temperature section ranges from 50° C. to 100° C.

22. The piezoelectric actuator module according to claim 21, wherein the first temperature section ranges from 450° C. to 475° C. and the second temperature section ranges from 525° C. to 550° C.

23. The piezoelectric actuator module according to claim 21, wherein the first piezoelectric material and the second piezoelectric material are imprinted to have polarization directions formed to be reverberated with respect to a direction coupled with each other.

24. The piezoelectric actuator module according to claim 23, wherein a first voltage section, in which the first piezoelectric material is imprinted and output, is higher than a second voltage section, in which the second piezoelectric material is imprinted and output.

25. The piezoelectric actuator module according to claim 24, wherein the first voltage section ranges from 5.84V to 3.54V and the second voltage section ranges from −0.86V to −0.28V.

26. The piezoelectric actuator module according to claim 21, wherein the electrode part of the multi-layer comprises:
a first electrode connected to the first piezoelectric material;
a second electrode connected to the second piezoelectric material; and
a third electrode disposed between the first piezoelectric material and the second piezoelectric material.

27. The piezoelectric actuator module according to claim 26, wherein for a stacked direction in which the multi-layer is coupled with the support layer,
wherein the second electrode is disposed at a lower end of the multi-layer and contacts the support layer,
wherein the second piezoelectric material is formed on an upper portion of the second electrode,
wherein the third electrode is formed between the second piezoelectric material and the first piezoelectric material,
wherein the first piezoelectric material is formed on an upper portion of the third electrode, and
wherein the first electrode is formed on an upper portion of the first piezoelectric material.

28. The piezoelectric actuator module according to claim 26, wherein an electrode to which the first electrode and the second electrode are connected is a ground electrode.

29. A MEMS sensor, comprising:
a flexible substrate comprising an excitation unit, a sensor, and a support layer;
a mass body connected to the flexible substrate; and
a post supporting the flexible substrate,
wherein the excitation unit is configured of a multi-layer which comprises a first piezoelectric material, a second piezoelectric material, and an electrode part connected to the first piezoelectric material and the second piezoelectric material,
wherein the first piezoelectric material is deposited in a first temperature section,
wherein the second piezoelectric material is deposited in a second temperature section, and
wherein the first temperature section is a higher temperature than the second temperature section or the first temperature section is a lower temperature than the second temperature section and a difference between the first temperature section and the second temperature section ranges from 50° C. to 100° C.

30. The MEMS sensor according to claim 29, wherein the first temperature section ranges from 525° C. to 550° C. and the second temperature section ranges from 4:50° C. to 475° C., or the first temperature section ranges from 450° C. to 475° C. and the second temperature section ranges from 525° C. to 550° C.

31. The MEMS sensor according to claim 29, wherein the first piezoelectric material and the second piezoelectric material are imprinted to have polarization directions formed in different directions.

32. The MEMS sensor according to claim 29, wherein when the first temperature section ranges from 525° C. to 550° C. and the second temperature section ranges from 450° C. to 475° C., a first voltage section, in which the first piezoelectric material is imprinted and output, is lower than a second voltage section, in which the second piezoelectric material is imprinted and output.

33. The MEMS sensor according to claim 32, wherein the first voltage section ranges from −0.86V to −0.28V and the second voltage section ranges from 5.84V to 3.54V.

34. The MEMS sensor according to claim 30, wherein when the first temperature section ranges from 450° C. to 475° C. and the second temperature section ranges from 525° C. to 550° C., a first voltage section, in which the first piezoelectric material is imprinted and output, is higher than a second voltage section, in which the second piezoelectric material is imprinted and output.

35. The MEMS sensor according to claim 34, wherein the first voltage section ranges from 5.84V to 3.54V and the second voltage section ranges from −0.86V to −0.28V.

36. The MEMS sensor according to claim 29, wherein the electrode part comprises:
a first electrode connected to the first piezoelectric material;
a second electrode connected to the second piezoelectric material; and
a third electrode disposed between the first piezoelectric material and the second piezoelectric material.

37. The MEMS sensor according to claim 36, herein for a stacked direction in which the multi-layer is coupled with the support layer,
wherein the second electrode is disposed at a lower end of the multi-layer and contacts the support part,
wherein the second piezoelectric material is formed on an upper portion the second electrode,
wherein the third electrode is formed between the second piezoelectric material and the first piezoelectric material, and
wherein the first piezoelectric material is formed on an upper portion of the third electrode and the first electrode is formed on an upper portion of the first piezoelectric material.
